(19) United States
(12) Patent Application Publication
(10) Pub. No.: US 2024/0120433 A1
(43) Pub. Date: Apr. 11, 2024

(54) MANUFACTURING METHOD OF SILICON CARBIDE THIN FILM FOR TRANSPARENT SOLAR CELL

(71) Applicant: ARCHE CO., LTD., Osan-si (KR)

(72) Inventors: Chan Uk JON, Cheonan-si (KR); Jun Yong BAK, Siheung-si (KR); Jae Kwang YOON, Hwaseong-si (KR)

(21) Appl. No.: 18/185,135

(22) Filed: Mar. 16, 2023

(30) Foreign Application Priority Data
Oct. 7, 2022 (KR) 10-2022-0128534

(51) Int. Cl. H01L 31/18; H01L 31/105

(52) U.S. Cl. CPC H01L 31/1804; H01L 31/105

(57) ABSTRACT

The present application relates to a manufacturing method of silicon carbide thin film for transparent solar cell, the method comprises forming a light-absorbing layer on a semiconductor substrate by applying plasma to a carbon source and a silicon source.

### CROSS-REFERENCE TO RELATED APPLICATIONS

This application claims the priority of Korean Patent Application No. 10-2022-0128534 filed on Oct. 7, 2022, in the Korean Intellectual Property Office, the disclosure of which is incorporated herein by reference.

### BACKGROUND

### Field

The present application relates to a manufacturing method of silicon carbide thin film for transparent solar cell.

### Description of the Related Art

Recently, as existing energy resources such as oil and coal are expected to be depleted, interest in alternative energy to replace them is increasing. Among them, solar cells are in the spotlight as next-generation batteries that convert solar energy into electrical energy.

A solar cell is a device that converts solar energy directly into electrical energy. A solar cell generates electricity using infinite solar energy and unlike other power generation systems, it is a quiet and safe eco-friendly system because it has no moving part.

In general, solar cells classify crystalline Si (polycrystalline and single crystalline) solar cells into I generation, compound semiconductor (III-V) and thin-film semiconductor (a-Si, CdTe, CIGS) solar cells into II generation, and organic and nano semiconductor materials into III generation.

Among them, a supply shortage of Si wafer is intensified in a crystalline Si solar battery, and there are problems of high costs caused by this supply imbalance, and additional cost reduction is not easy. In addition, thin-film solar cells have a problem that their energy conversion efficiency is much lower than that of crystalline Si solar cells. In order to commercialize a solar cell, a method of manufacturing a transparent solar cell having excellent productivity while improving the efficiency of the solar cell is required. Currently, solar cells using new materials are being developed, but there is a problem of low performance and manufacturing efficiency, and thus improvement of a manufacturing method of solar cells is required.

Korean Patent Application Publication No. 2008-0044183, which is the background technology of this application, relates to amorphous-crystalline tandem nanostructured solar cells.

### SUMMARY

The present application is to solve the aforementioned problems of the conventional art, and an object of the present application is to provide a manufacturing method of silicon carbide thin film for transparent solar cell.

However, the technical tasks to be achieved by the example of the present application are not limited to the technical tasks as described above, and other technical tasks may exist.

As a technical means for achieving the above-mentioned technical tasks, a first aspect of the present application provides a method of manufacturing a silicon carbide thin film for a transparent solar cell includes forming a light-absorbing layer on a semiconductor substrate by applying plasma to a carbon source and a silicon source, wherein the light-absorbing layer includes amorphous silicon carbide.

According to an embodiment of the present application, the semiconductor substrate may include a support substrate and an n-type semiconductor or a p-type semiconductor formed on the support substrate, but the present application is not limited thereto.

According to an embodiment of the present application, each of the n-type semiconductor and the p-type semiconductor may independently include one selected from the group consisting of silicon carbide, Si, GaAs, CdTe, CdS, InP, and combinations thereof, but the present application is not limited thereto.

According to an embodiment of the present application, the n-type semiconductor and the p-type semiconductor may include silicon carbide, but the present application is not limited thereto.

According to an embodiment of the present application, the ratio of carbon and silicon of the n-type semiconductor, the ratio of carbon and silicon of the light absorption layer, and the ratio of carbon and silicon of the p-type semiconductor may be different, but the present application is not limited thereto.

According to an embodiment of the present application, depending on the ratio of carbon and silicon, wavelengths of light absorbed by the n-type semiconductor, the light absorption layer, and the p-type semiconductor may be different, but the present application is not limited thereto.

According to an embodiment of the present application, the n-type semiconductor and the p-type semiconductor layer may each independently include a step of forming doped amorphous silicon carbide by applying plasma to a source and a dopant, and a step of annealing the amorphous silicon carbide, but the present application is not limited thereto.

According to an embodiment of the present application, the source may include CH₄, and the dopant may include one selected from the group consisting of N₂, B₂H₆, trimethylamine (TMA), PH₃, and combinations thereof, but the present application is not limited thereto.

According to an embodiment of the present application, the carbon source may include CH₄, but the present application is not limited thereto.

According to an embodiment of the present application, the silicon source may include SiH₄, but the present application is not limited thereto.

According to an embodiment of the present application, the step of forming the light absorption layer may be independently performed in an environment in which hydrogen, nitrogen, or oxygen gas is injected, but the present application is not limited thereto.

The above-described problem solving means are merely exemplary, and should not be construed as an intention of limiting the present application. In addition to the embodiments described above, additional embodiments may exist in the drawings and detailed description of the invention.

The method of the manufacturing method of silicon carbide thin film for transparent solar cell according to the present invention is to adjust the ratio of Si and C when manufacturing a SiC solar cell. In this regard, when the content of Si in the SiC solar cell is increased, the band gap of the solar cell is narrowed, and thus the J_{sc} performance may be improved, and when the content of C is increased, the band gap is widened and the V_{OC} performance may be improved.

Further, the manufacturing method of a transparent solar cell in accordance with this disclosure can reduce defects by adding hydrogen, nitrogen, or small gas when the contents of Si and C are controlled.

Further, the manufacturing method of a transparent solar cell according to this application, by arranging SiC having various compositions of Si and C in a multi-layer structure, sunlight can be efficiently absorbed in the multi-layer, hence improving the efficiency of the absorption layer.

However, the effects obtainable in the present application are not limited to the effects as described above, and another effect may exist.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 shows a schematic diagram of the manufacturing method of a transparent solar cell according to one Example of the present application.

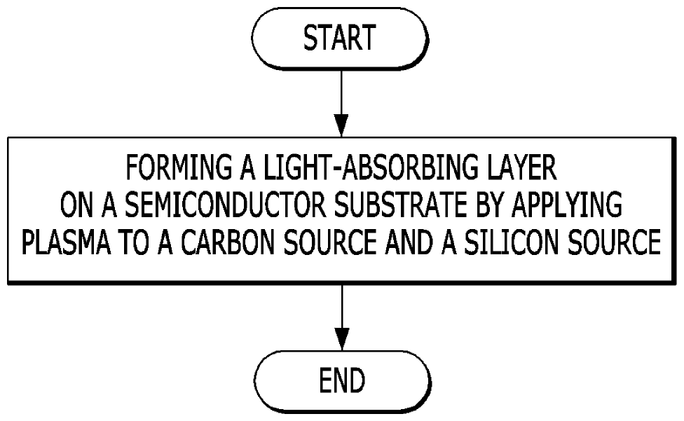

### DETAILED DESCRIPTION OF THE EMBODIMENT

Hereinafter, embodiments of the present application will be described in detail with reference to the accompanying drawings so that those with ordinary skill in the art to which the present application pertains will easily be able to implement the present application.

However, the present application may be implemented in various different forms and is not limited to the embodiments described herein. Further, parts irrelevant to the description are omitted in order to clearly describe the present application in the drawings, and similar reference numerals are attached to similar parts throughout the specification.

In the whole specification of the present application, when a part is said to be “connected” with other parts, it not only includes a case that the part is “directly connected” to the other parts, but also includes a case that the part is “electrically connected” to the other parts with another element being interposed therebetween.

In the whole specification of the present application, when any member is positioned “on”, “over”, “above”, “beneath”, “under”, and “below” other member, this not only includes a case that the any member is brought into contact with the other member, but also includes a case that another member exists between two members.

In the whole specification of the present application, if a prescribed part “includes” a prescribed element, this means that another element may be further included instead of excluding other elements unless any particularly opposite description exists.

When unique manufacture and material allowable errors of numerical values are suggested to mentioned meanings of terms of degrees used in the present specification such as “about”, “substantially”, etc., the terms of degrees are used in the numerical values or as a meaning near the numerical values, and the terms of degrees are used to prevent that an unscrupulous infringer unfairly uses a disclosure content in which exact or absolute numerical values are mentioned to help understanding of the present application. Further, in the whole specification of the present application, “a step to do ˜” or “a step of ˜” does not mean “a step for ˜”.

In the whole specification of the present application, a term of “a combination thereof” included in a Markush type expression, which means a mixture or combination of one or more selected from the group consisting of constituent elements described in the Markush type expression, means including one or more selected from the group consisting of the constituent elements.

In the whole specification of the present application, description of “A and/or B” means “A or B, or, A and B”.

Hereinafter, a manufacturing method of silicon carbide thin film for transparent solar cell according to the present application will be described in detail with reference to embodiments, examples, and drawings. However, the present application is not limited to such embodiments, examples, and drawings.

As a technical means for achieving the above-mentioned technical tasks, the first aspect of the present application provides a manufacturing method of silicon carbide thin film for transparent solar cell includes forming a light-absorbing layer on a semiconductor substrate by applying plasma to a carbon source and a silicon source, wherein the light-absorbing layer includes amorphous silicon carbide.

According to an embodiment of the present application, the semiconductor substrate may include a support substrate and an n-type semiconductor or a p-type semiconductor formed on the support substrate, but is not limited thereto.

In this regard, the method of manufacturing a silicon carbide thin film for a solar cell according to the present invention may further include, but is not limited to, forming an n-type semiconductor or a p-type semiconductor on the support substrate.

In accordance with this disclosure's embodiment, the n-type semiconductor and the p-type semiconductor layer can independently be formed by applying plasma on a carbon source, a silicon source, and a dopant for forming a amorphous silicon carbide, and annealing the amorphous silicon carbide.

According to an embodiment of the present application, the n-type semiconductor, the light absorption layer, and the p-type semiconductor may independently include, but are not limited to, Si, GaAs, CdTe, CdS, InP, and combinations thereof.

According to an embodiment of the present application, the n-type semiconductor and the p-type semiconductor may include SiC, but are not limited thereto.

According to an embodiment of the present application, a ratio of Si and C of the n-type semiconductor, a ratio of Si and C of the light-absorbing layer, and a ratio of Si and C of the p-type semiconductor may be different, but are not limited thereto.

According to an embodiment of the present application, wavelengths of light absorbed by the n-type semiconductor, the light absorption layer, and the p-type semiconductor may vary depending on the ratio of carbon and silicon, but are not limited thereto.

According to an embodiment of this disclosure, the carbon source may include CH₄, the silicon source may include SiH₄, and the dopant may include one selected from the group consisting of N₂, B₂H₆, trimethylamine (TMA), PH₃, and combinations thereof, but is not limited thereto.

According to an embodiment of the present application, the step of forming the light-absorbing layer may be performed in an environment in which hydrogen, nitrogen, or oxygen gas is injected, but is not limited thereto.

According to an embodiment of the present invention, the ratio of carbon and silicon may be 1.8 to 2.2, but is not limited thereto.

According to an embodiment of the present application, amorphous silicon carbide may be formed by applying plasma to the carbon source and the silicon source. In this case, when plasma is applied on the dopant together with the source, a part of atoms or molecules constituting the dopant may be doped on the silicon carbide to dope the amorphous silicon carbide in an n-type or p-type.

Specifically, when the dopant is N2 or B2H6, the amorphous SiC may be doped in an n type, and when the dopant is TMA or PH3, the amorphous SiC may be doped in a p type. As will be described later, amorphous SiC formed without applying plasma to the dopant may function as a light absorption layer.

According to an embodiment of the present application, the method may further include forming a semiconductor substrate including a p-type semiconductor or an n-type semiconductor on the light absorption layer, but is not limited thereto.

In other words, the light absorption layer may be a p-type semiconductor and an n-type semiconductor, or an n-type semiconductor and a p-type semiconductor, but is not limited thereto.

According to an embodiment of the present application, the step of forming the light-absorbing layer may be performed in an environment in which hydrogen, nitrogen, or oxygen gas is injected, but is not limited thereto.

According to an embodiment of the present application, the step of forming the n-type semiconductor and the step of forming the p-type semiconductor may be independently performed in an environment in which hydrogen, nitrogen, or oxygen gas is injected, but are not limited thereto.

Hydrogen, nitrogen, and oxygen gas may be added to reduce defects that occur when a ratio of carbon and silicon is adjusted in the process of forming the n-type semiconductor, p-type semiconductor, and the light absorption layer.

The foregoing description of the present application is for illustration, and those with ordinary skill in the art to which the present application pertains will be able to understand that it may be easily modified into other specific forms without changing the technical spirit or essential features of the present application. Therefore, it should be understood that the embodiments described above are illustrative in all respects and not restrictive. For example, each element described as a single form may be implemented in a dispersed form, and likewise elements described in the dispersed form may also be implemented in a combined form.

The scope of the present application is indicated by the claims to be described later rather than the above detailed description, and all changes or modified forms derived from the meaning and scope of the claims and equivalent concepts thereof should be construed as being included in the scope of the present application.

What is claimed is:

1. A manufacturing method of silicon carbide thin film for transparent solar cell, the method comprising:
forming a light-absorbing layer on a semiconductor substrate by applying plasma to a carbon source and a silicon source,
wherein the light-absorbing layer includes amorphous silicon carbide.

2. The method of claim 1, wherein the semiconductor substrate includes a support substrate and an n-type semiconductor or a p-type semiconductor formed on the support substrate.

3. The method of claim 2, wherein the n-type semiconductor and the p-type semiconductor each independently include those selected from the group consisting of Si, silicon carbide, GaAs, CdTe, CdS, InP, and combinations thereof.

4. The method of claim 3, wherein the n-type semiconductor and the p-type semiconductor include silicon carbide.

5. The method of claim 4, wherein the ratio of carbon and silicon of the n-type semiconductor, the ratio of carbon and silicon of the light-absorbing layer, and the ratio of carbon and silicon of the p-type semiconductor are different.

6. The method of claim 5, wherein depending on the ratio of carbon and silicon, wavelengths of light absorbed by the n-type semiconductor, the light absorption layer, and the p-type semiconductor are different.

7. The method of claim 1, wherein the carbon source includes CH₄.

8. The method of claim 1, wherein the silicon source includes SiH₄.

9. The method of claim 1, wherein the step of forming the light absorption layer is performed in an environment in which hydrogen, nitrogen, or oxygen gas is injected.
